(19) United States
(12) Patent Application Publication
(10) Pub. No.: US 2026/0090299 A1
(43) Pub. Date: Mar. 26, 2026

(54) Basal Plane Dislocation Mitigation via Etching and Growth Interrupts

(71) Applicant: The Government of the United States of America, as represented by the Secretary of the Navy, Arlington, VA (US)

(72) Inventors: Rachael L. Myers-Ward, Washington, DC (US); Nadeem Mahadik, Washington, DC (US)

(73) Assignee: The Government of the United States of America, as represented by the Secretary of the Navy, Arlington, VA (US)

(21) Appl. No.: 19/334,184

(22) Filed: Sep. 19, 2025

Related U.S. Application Data
(60) Provisional application No. 63/697,089, filed on Sep. 20, 2024.

(51) Int. Cl. H01L 21/04; H01L 21/3065; H01L 21/322

(52) U.S. Cl. CPC H10P 50/00; H10P 36/00; H10P 50/242

(57) ABSTRACT

A method of preventing basal plane dislocations (BPDs) from expanding from a SiC substrate or a highly doped buffer layer into an epitaxial device/active layer comprising the steps of providing a substrate, etching the substrate, converting BPDs to electrically benign threading edge dislocations, growing a first buffer layer on the substrate, creating a growth interrupt layer or second etch layer, growing a second buffer layer, growing a drift layer, and preventing BPDs from expanding into the drift layer. A device capable of preventing basal plane dislocations (BPDs) from expanding from a SiC substrate or a highly doped buffer layer into an epitaxial device/active layer comprising a substrate, a first buffer layer, a growth interrupt layer or etch layer, a second buffer layer and a drift layer. The drift layer carrier lifetime is not reduced. BPD expansion is prevented at current densities up to 12 kA/cm².

### REFERENCE TO RELATED APPLICATION

This application is a non-provisional of, and claims priority to and the benefits of, U.S. Provisional Patent Application No. 63/697,089 filed on Sep. 20, 2024, the entirety of which is herein incorporated by reference.

### FEDERALLY-SPONSORED RESEARCH AND DEVELOPMENT

The United States Government has ownership rights in this invention. Licensing inquiries may be directed to Office of Technology Transfer, US Naval Research Laboratory, Code 1004, Washington, DC 20375, USA; +1.202.767.7230; techtran@nrl.navy.mil, referencing Navy Case #211791.

### BACKGROUND

This disclosure concerns basal plane dislocation mitigation via etching and growth interrupts.

Disclosed herein is a method to prevent basal plane dislocations (BPDs) in silicon carbide (SiC) wafers from propagating into the active region of devices during device operation, especially for, but not limited to, high current densities and pulsed power applications.

The invention entails a two-step process. First, we use an etch prior to growth to convert BPDs to electrically benign threading dislocations within a thin, highly doped buffer layer. Second, after the buffer layer growth, a growth interrupt is used to prevent BPDs from propagating and expanding into the device epitaxial layer by mechanisms including, but not limited to, reduction of the carrier lifetime within the epitaxial buffer layer.

BPDs significantly degrade device performance by increasing the forward voltage drift in bipolar SiC devices.

Therefore, our method solves this problem by preventing BPDs from entering the active region of devices.

A novel method and product are described herein concerning a device capable of high current density biasing without basal plane dislocations (BPDs) expanding from a SiC substrate or a highly doped buffer layer into an epitaxial device/active layer comprising a substrate, a first etch layer on the substrate, a first buffer layer on the first etch layer, a second etch layer or a growth interrupt layer on the buffer layer, and a thin second buffer layer followed by a drift layer on the second etch layer or growth interrupt layer.

Basal plane dislocations (BPDs) have been a problem for SiC high-voltage bipolar devices for many years as they source Shockley-type stacking faults in the presence of an electron-hole plasma and reduce minority carrier lifetimes [J. P. Bergman, et. al., Mater. Sci. Forum Vol. 353-356, 299 (2001).].

Upon device operation, the forward voltage drifts and the reverse leakage current increases for these bipolar devices.

Another problem is these BPDs are sourced from the substrate and propagate into the epitaxial layers during epitaxial growth of SiC.

While some of the BPDs convert to electrically benign threading dislocations at the substrate/epilayer interface, the density of BPDs in untreated epilayers can range between 100-1000 cm⁻².

Therefore, significant efforts have focused on reducing BPDs in the active region of devices to prevent device degradation.

Over the years, many researchers have developed in-situ and ex-situ techniques to reduce the density of BPDs in the epitaxial layers. One reference uses a KOH etch prior to growth to form etch pits into the substrate surface to convert BPDs at the substrate/epilayer interface [Z. Zhang, E. Moulton, and T. S. Sudarshan, Appl. Phys. Lett. 89, 081910 (2006).]. Another process uses a high temperature pre-growth annealing of the substrate prior to growth to reduce the density of BPDs in the epitaxial layer [N. A. Mahadik, et al. Mater. Sci. Forum 858, 233 (2016).]. A proton implantation after growth was found to reduce the density of stacking faults sourced from BPDs, however, even at the highest dose, there were at least 15 BPD/cm² after implantation [M. Kato, Sci. Rep., 12, 18790 (2022).]

Here at the US Naval Research Laboratory (NRL) our patents use a high temperature (greater than 1600° C.) H₂ etch prior to growth to reduce basal plane dislocations [U.S. Pat. Nos. 10,256,094 and 10,256,090]. Another NRL patent uses a growth interrupt to convert BPDs into electrically benign threading edge dislocations [U.S. Pat. No. 8,652,255].

H2 etching was done previously on PVT SiC substrates to convert the BPD to TED by forming nanopits with the purpose of reducing the number of perfect BPDs into the epitaxial layer. Interrupted epitaxial growth was done to convert BPDs to TED within the epilayer stack, works in 8 deg offcut wafers. This reduces perfect BPDs in the epilayer.

Here, we are not targeting reduction of perfect BPDs in epilayer, rather faulting and propagation of PBD partials from substrates or highly doped buffers into the device active drift layer during surge current or high pulsed current conditions.

Herein we disclose a method of basal plane dislocation mitigation via etching and/or growth interrupts.

Our method prevents basal plane dislocations (BPDs) in silicon carbide (SiC) wafers from propagating into the active region of devices during device operation.

As such, we demonstrate a solution to the long-standing problems discussed above.

### SUMMARY OF DISCLOSURE

### Description

This disclosure concerns a method to prevent basal plane dislocations (BPDs) in silicon carbide (SiC) wafers from propagating into the active region of devices during device operation, especially for, but not limited to, high current densities and pulsed power applications.

The invention entails a two-step method, which first uses an etch prior to growth to convert BPDs to electrically benign threading dislocations within a thin, highly doped buffer layer. The second step takes place after the buffer layer growth, where a growth interrupt is used to prevent BPDs from propagating and expanding into the device epitaxial layer by mechanisms including, but not limited to, reduction of the carrier lifetime within the epitaxial buffer layer.

It has been demonstrated that BPDs significantly degrade device performance by increasing the forward voltage drift in bipolar SiC devices, therefore, preventing BPDs from entering the active region of devices is essential.

A novel method and product are described herein concerning a device capable of preventing basal plane dislocations (BPDs) from expanding from a SiC substrate or a highly doped buffer layer into an epitaxial device/active layer comprising a substrate, etching, a buffer layer, a second etch layer or a growth interrupt layer on the buffer layer, and a thin second buffer layer followed by a drift layer on the second etch layer or growth interrupt layer.

One novelty is using the two steps (H2 etch and either the second H2 etch or the growth interrupt together).

Our method prevents BPDs from expanding from the substrate or buffer layer into the device layer under high current densities, such as a power density of 13 kW/cm².

### DESCRIPTION OF THE DRAWINGS

The following description and drawings set forth certain illustrative implementations of the disclosure in detail, which are indicative of several exemplary ways in which the various principles of the disclosure may be carried out. The illustrated examples, however, are not exhaustive of the many possible embodiments of the disclosure. Other objects, advantages and novel features of the disclosure will be set forth in the following detailed description when considered in conjunction with the drawings.

FIG. 1 illustrates a growth schedule of double H₂ etch process.

FIG. 2 illustrates an epitaxial stack of double etch process for the suppression of BPD expansion into epitaxial layers.

FIG. 3 illustrates UVPL images of double H₂ etch process pre-stressing (left) and after 1000 s at 13 kW/cm⁻² (right).

FIG. 4 illustrates a growth schedule of a hydrogen etch prior to growth, followed by a growth interrupt after the highly doped buffer layer.

FIG. 5 illustrates an epitaxial stack of the H₂ etch with a growth interrupt process for the suppression of BPD expansion into epitaxial layers.

FIG. 6 illustrates UVPL images of the H₂ etch with a growth interrupt process pre-stressing (left) and after 1900 s at 13 kW/cm⁻² (right) showing no BPDs after stressing.

### DETAILED DESCRIPTION OF THE INVENTION

This disclosure teaches methods and devices for preventing basal plane dislocations (BPDs) from expanding from a SiC substrate or a highly doped buffer layer into an epitaxial device/active layer comprising the steps of providing a substrate, etching the substrate and creating a first etch layer, growing a buffer layer on the first etch layer, creating a growth interrupt layer on the first buffer layer or etching the first buffer layer and creating a second etch layer, and growing a drift layer on the second etch layer.

A novel product is described herein concerning a device capable of preventing basal plane dislocations (BPDs) from expanding from a SiC substrate or a highly doped buffer layer into an epitaxial device/active layer comprising a substrate, a first etch layer on the substrate, a buffer layer on the first etch layer, a second etch layer or a growth interrupt layer on the buffer layer, and a drift layer on the second etch layer or growth interrupt layer.

Disclosed herein is a method of preventing BPDs from expanding from the SiC substrate or highly doped buffer layer into the epitaxial device/active layer upon device operation or an electron-hole plasma.

The invention includes a multi-step process. The substrate is SiC, n-type, p-type or SI. The substrate is first etched or annealed prior to epitaxial growth. The etching or annealing takes place in an inert gas, hydrogen or precursors/hydrogen gas mixture or an inert gas/hydrogen mixture or an inert gas/hydrogen/precursor gas mixture with the carrier gas flowing between 1-200 slm at temperatures between 1400-1800° C.

The pressure ranges from 10-900 mbar. The time of the etch ranges from 1 min-2 hr. Upon completing the etch, a highly doped epitaxial layer is grown for a desired amount of time. This results in a 0.1-20 μm thick epitaxial layer.

The following step is to perform a growth interrupt, while eliminating some or all precursors from the growth chamber. The growth interrupt occurs between growth temperature and room temperature. The sample is removed from the chamber before the next growth step, or left in the chamber.

The temperature is brought back to growth temperature if different from the growth interrupt temperature, then a highly doped film is grown, followed by a low doped active layer. Alternatively, a buffer layer is grown prior to the low doped active layer.

Another embodiment is replacing the growth interrupt with a second etch or anneal, using similar conditions to the first etch.

Herein, we demonstrate a solution to the long-standing problems in the prior art of device degradation.

Basal plane dislocations (BPDs) have been a problem for SiC high-voltage bipolar devices for many years as they source Shockley-type stacking faults in the presence of an electron-hole plasma and reduce minority carrier lifetimes. In the prior art, upon device operation, the forward voltage drifts and the reverse leakage current increases for these bipolar devices.

Another problem in the prior art is these BPDs are sourced from the substrate and propagate into the epitaxial layers during epitaxial growth of SiC.

We demonstrate a method and device to solve these problems.

### Example 1

In one embodiment, a double H₂ etch was performed where the SiC substrate was first brought up to an etch temperature of 1665° C. in 80 slm H₂ and 70 mbar. The sample was held for 50 min under these conditions. Then, the pressure was increased to 100 mbar and reactor temperature was reduced to a growth temperature of 1620° C., at which point, the precursors were ramped over 5 min.

A highly doped buffer layer was grown for 6 μm at 5 μm/h, resulting in an electron concentration of ˜3×18¹⁸ cm⁻³.

The precursors were then stopped, the pressure was changed to 70 mbar and the temperature was raised to 1665° C.

The sample was etched for 50 min.

Then, the pressure was increased to 100 mbar and the temperature was decreased again to 1620° C. and precursors were introduced to grow a 0.5 μm buffer layer.

A 15 μm drift layer was then grown at 10 μm/h with an electron concentration of 5×10¹⁵ cm⁻³.

The precursors were then terminated and the sample was then cooled to room temperature in H₂.

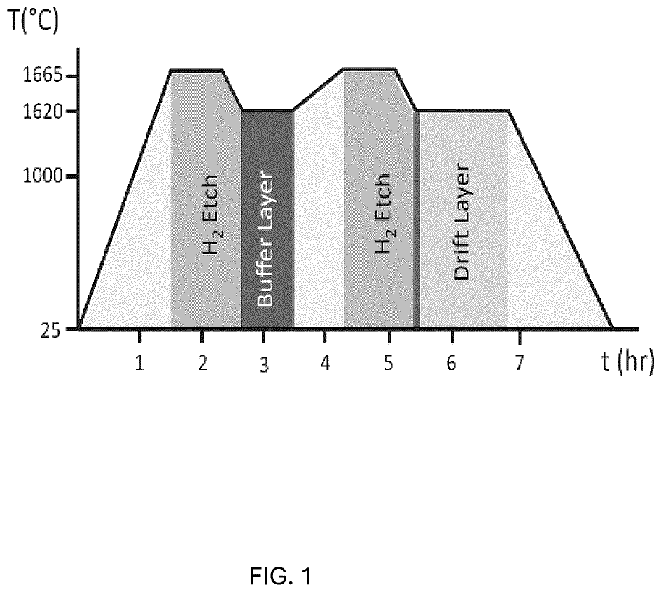

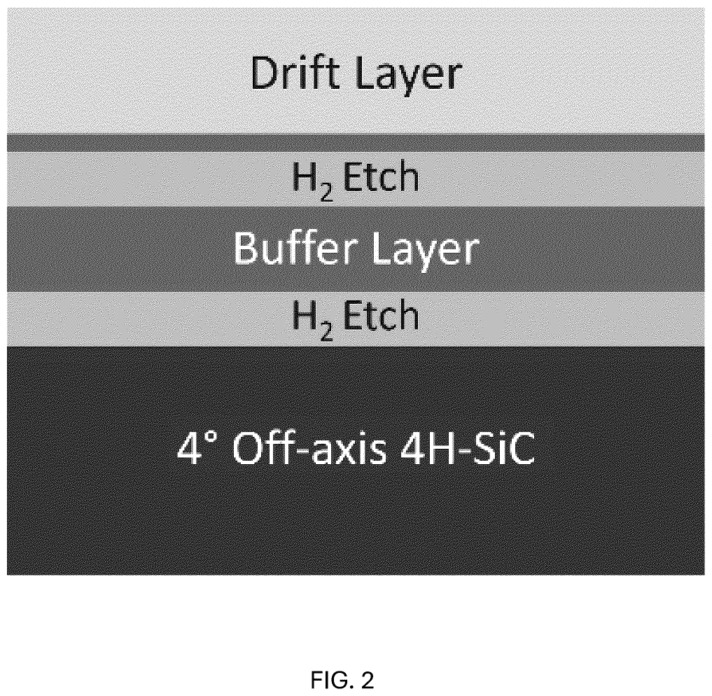

The growth schedule and epitaxial layer stack for this process is shown in FIG. 1 and FIG. 2, respectively.

Using this method, BPDs did not expand until a power density of 13 kW/cm² was applied, where ˜50 cm⁻² expanded.

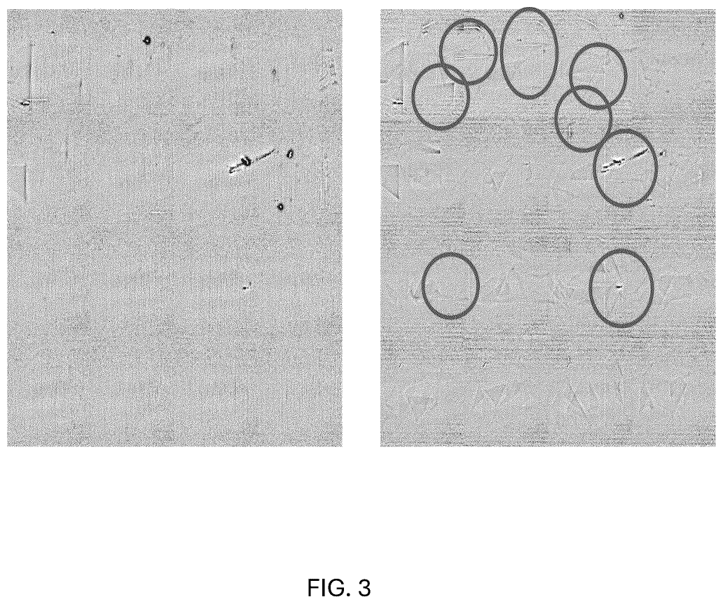

An ultraviolet photoluminescence (UVPL) image is shown in FIG. 3 demonstrating the BPD expansion after applying 13 kW/cm².

### Example 2

In another embodiment, a H₂ etch followed by a growth interrupt was performed where the SiC substrate was first brought up to an etch temperature of 1665° C. in 80 slm H₂ and 70 mbar.

The sample was held for 50 min under these conditions.

The reactor temperature was reduced to a growth temperature of 1620° C. at which point, the pressure was increased to 100 mbar and the precursors were ramped up over 5 min.

A highly doped buffer layer was grown for 6 μm at 5 μm/h, resulting in an electron concentration of ˜3×18¹⁸ cm⁻³.

The precursors were stopped and the temperature was reduced to 1000° C.

Upon reaching the growth interrupt temperature, the temperature was then brought back to growth temperature of 1620° C. and precursors were introduced to grow a 0.5 μm buffer layer.

A 15 μm drift layer was then grown at 10 μm/h with an electron concentration of 5×10¹⁵ cm⁻³.

The precursors were then terminated and the sample was cooled to room temperature in H₂.

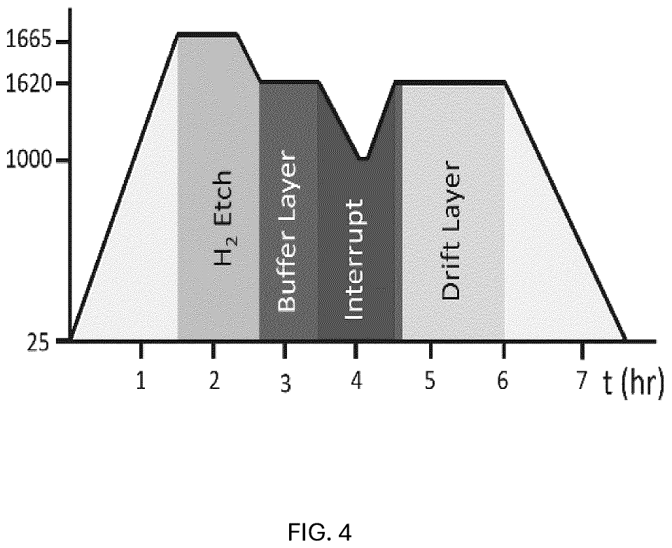

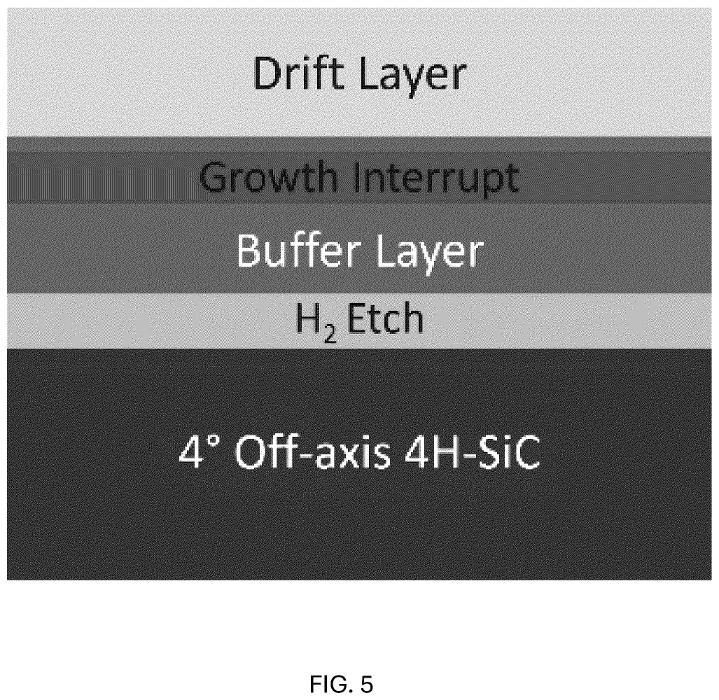

The growth schedule and epitaxial layer stack for this process is shown in FIG. 4 and FIG. 5, respectively.

Using this process, no BPDs expanded into the epitaxial layer when stressed with a power density of 13 kW/cm².

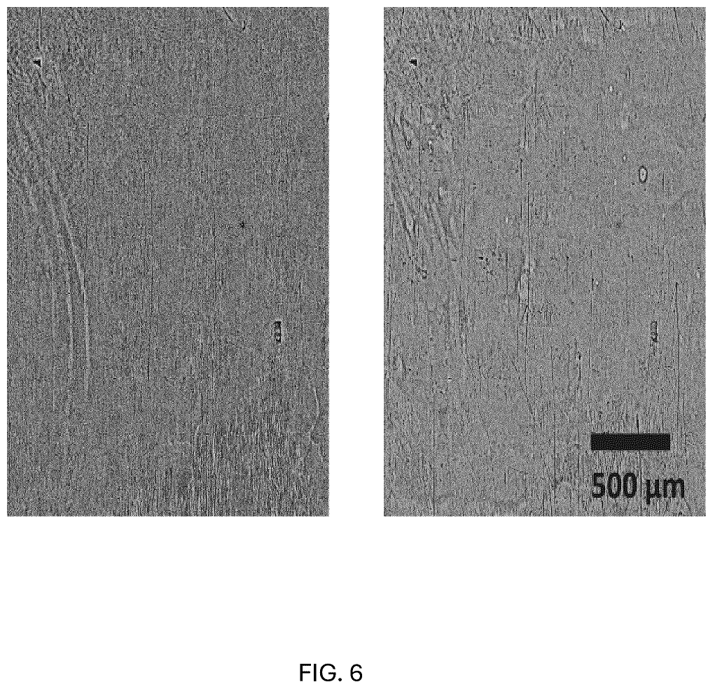

An ultraviolet photoluminescence (UVPL) image is shown in FIG. 6, demonstrating the BPD expansion after applying 13 kW/cm².

### Example 3

In another embodiment, the H₂ etch was replaced with an Ar anneal before growth and the growth interrupt was conducted using Ar gas instead of H₂.

The growth conditions were similar to the previous embodiments, with the exception of the following.

The sample was ramped in 5 slm Ar and 200 mbar to 1400° C., at which time the pressure was decreased to 70 mbar and the temperature was raised to ˜1635° C.

The sample was annealed in 5 slm Ar and 70 mbar for 50 min.

The carrier gas of Ar was then switched to 80 slm of H₂ under 100 mbar and then the sample temperature was reduced to a growth temperature of 1620° C.

A highly doped buffer layer was grown for 6 μm at 5 μm/h, resulting in an electron concentration of ˜3×18¹⁸ cm⁻³.

The precursors were terminated and the gas was switched to 5 slm Ar.

The temperature was reduced to 1000° C. and upon reaching the growth interrupt temperature, the temperature was then brought back to growth temperature of 1620° C. under 200 mbar.

The carrier gas was switched back to 80 slm H₂ and 100 mbar and precursors were introduced to grow a 0.5 μm buffer layer.

A 15 μm drift layer was then grown at 10 μm/h with an electron concentration of 5×10¹⁵ cm⁻³.

The precursors were then terminated and the sample was cooled to room temperature in H₂.

Using this method, BPDs did penetrate the epilayer before exposure of 1000 W/cm², but in a low density.

### Example 4

In another embodiment, a thin buffer layer was used along with a growth interrupt.

Here, conditions were similar to that outlined in the H₂ etch plus growth interrupt. However, the initial buffer layer was 0.4 μm thick and the buffer layer after the growth interrupt was 1 μm thick.

All other conditions were the same.

There was no BPD expansion up to 100 W/cm², but the BPDs did expand at 1 kW/cm².

### Example 5

In another embodiment, a thin buffer layer and growth interrupt were used.

Again, the conditions were similar to the H₂ etch plus growth interrupt, but the initial buffer layer was 1 μm thick and the follow on buffer layer after the H₂ etch was 0.2 μm thick.

The BPDs did not expand up to 1 kW/cm², indicating a thinner buffer layer can be used for this process.

### Example 6

Use of other gases during etching or annealing include but are not limited to: Ar, Ar/H₂. H₂, N₂, precursors, and any mixture thereof.

The time of the etch ranges from 1 min-2 h.

The temperature of the etch ranges from 1400-1800° C.

The pressure ranges from 5-900 mbar.

Flow of carrier gas ranges from 1-200 slm.

### Example 7

The ramp to growth temperature takes place in H₂, Ar, Ar/H₂, with or without carbon precursor.

The thickness of the highly doped layer is 0.1-20 μm thick.

The growth interrupt uses similar gases to those in the etching or annealing process.

The temperature ranges from room temperature to 1800° C.

The pressure ranges from 5-900 mbar.

The carrier flow ranges between 1 and 200 slm.

The sample is removed from the growth chamber during the growth interrupt.

The time varies from 1 min-2 h.

The layer after the growth interrupt is unintentionally doped, low doped or highly doped material.

For the success of bipolar SiC high power devices, SiC epitaxial layers need to be free of basal plane dislocations (BPDs) as they source Shockley-type stacking faults in the presence of an electron-hole plasma and cause forward voltage drifts, leading to device failure. Research has been conducted over the years to mitigate the expansion of BPDs propagating from the substrate into the epitaxial device layers. While these ex-situ and in-situ processes have been extremely successful, limiting the ˜200-1000 BPD/cm² in the substrate from penetrating into the epitaxial layers, the issue remains that under high current densities (>1000 A/cm²), the injected carrier concentration is sufficiently high to expand the BPDs from the substrate into the epitaxial layer, thus becoming device killers.

We developed an in-situ growth process that incorporates a H₂ etch prior to the growth of the buffer layer to convert BPDs to electrically benign threading edge dislocations, followed by a growth interrupt between the buffer layer and the drift layer, which significantly quenches the buffer layer lifetime, preventing BPDs from expanding into the drift layer during high current densities.

Note the drift layer carrier lifetime is not reduced.

Using our new process, we successfully demonstrated the prevention of BPD expansion at current densities up to 12 kA/cm².

We have also incorporated our novel growth technique to commercially grown, full 150 mm wafers, and investigated its robustness, demonstrating a lab-to-fab transition, its manufacturability and ultimate impact of the novel defect mitigation process.

### Advantages and New Features

1) The etch or anneal prior to growth is conducted to increase the conversion of BPDs to threading edge dislocations.
2) This enables a low density of BPDs in the highly doped buffer layer.
3) The growth interrupt after the buffer layer reduces the carrier lifetime of the material, thus reducing the ability for enough electron-hole recombination energy at the BPDs, including BPD partials, to cause them to expand into Shockley faults, and expand into the epitaxial layer.
4) Both the H2 etch before growth and the growth interrupt have been patented by us here at the US Naval Research Laboratory. However, this is a new feature with a highly doped buffer layer between them and using the two processes together.
5) A key difference is that the growth interrupt disclosed herein occurs at a lower temperature of 1000° C., which is key to cause carrier lifetime reduction.
6) The prior art does not prevent BPD expansion at high current densities.
7) The prior art did not prevent the expansion of BPDs under high power density stressing or high current densities.
8) Therefore, it was not known this current method disclosed herein would result in the suppression of BPD expansion under high power densities.

The above examples are merely illustrative of several possible embodiments of various aspects of the present disclosure, wherein equivalent alterations and/or modifications will occur to others skilled in the art upon reading and understanding this specification and the annexed drawings. In addition, although a particular feature of the disclosure may have been illustrated and/or described with respect to only one of several implementations, such feature may be combined with one or more other features of the other implementations as may be desired and advantageous for any given or particular application. Also, to the extent that the terms “including”, “includes”, “having”, “has”, “with”, or variants thereof are used in the detailed description and/or in the claims, such terms are intended to be inclusive in a manner similar to the term “comprising”.

What we claim is:

1. A method of preventing basal plane dislocations (BPDs) from expanding from a SiC substrate or a highly doped buffer layer into an epitaxial device/active layer, comprising the steps of:
providing a substrate;
etching the substrate;
converting BPDs to electrically benign threading edge dislocations;
growing a first buffer layer on the substrate;
creating a growth interrupt layer or second etch layer on the first buffer layer;
growing a second buffer layer on the growth interrupt layer or second etch layer;
growing a drift layer on the second buffer layer; and
preventing BPDs from expanding into the drift layer.

2. The method of preventing basal plane dislocations (BPDs) from expanding from a SiC substrate or a highly doped buffer layer into an epitaxial device/active layer of claim 1, comprising the steps of:
preventing BPD expansion at current densities up to 12 kA/cm².

3. The method of preventing basal plane dislocations (BPDs) from expanding from a SiC substrate or a highly doped buffer layer into an epitaxial device/active layer of claim 2, further comprising the steps of:
performing the step of etching the substrate in an inert gas, hydrogen gas, or precursors/hydrogen or a combination of gas mixture with the gas flowing between 1-200 slm at temperatures between 1400-1800 °C;
performing the step of etching the substrate in a pressure of 10-900 mbar; and
performing the step of etching the substrate for 1 min-2 hr.

4. The method of preventing basal plane dislocations (BPDs) from expanding from a SiC substrate or a highly doped buffer layer into an epitaxial device/active layer of claim 3, wherein
wherein the substrate is SiC; and
wherein the SiC substrate is n-type, p-type, or semi-insulating (SI).

5. The method of preventing basal plane dislocations (BPDs) from expanding from a SiC substrate or a highly doped buffer layer into an epitaxial device/active layer of claim 4, further comprising the steps of:
performing the step of etching the substrate at a temperature of 1665° C. in 80 slm H₂ and 70 mbar;
performing the step of etching the substrate for 50 min wherein the step of etching comprises the steps of
increasing the pressure to 100 mbar;
reducing the temperature to 1620° C.;
growing the buffer layer to 6 μm at 5 μm/h;
resulting in an electron concentration of ˜3×18¹⁸ cm⁻³. reducing the pressure to 70 mbar;
increasing the temperature to 1665° C.;
maintaining the conditions for 50 min;
increasing the pressure to 100 mbar;
decreasing the temperature to 1620° C.;
growing a 0.5 μm second etch layer; and
growing a 15 μm drift layer at 10 μm/h with an electron concentration of 5×10¹⁵ cm⁻³.

6. The method of preventing basal plane dislocations (BPDs) from expanding from a SiC substrate or a highly doped buffer layer into an epitaxial device/active layer of claim 5, wherein
basal plane dislocations (BPDs) did not expand until a power density of 13 kW/cm² was applied; and
wherein ˜50 cm⁻² expanded.

7. A capable of preventing basal plane dislocations (BPDs) from expanding from a SiC substrate or a highly doped buffer layer into an epitaxial device/active layer, comprising:
a substrate;
a first buffer layer on the substrate;
a growth interrupt layer or etch layer on the first buffer layer on the substrate;
a second buffer layer on the growth interrupt layer or etch layer; and
a drift layer on the second buffer layer.

8. A device capable of preventing basal plane dislocations (BPDs) from expanding from a SiC substrate or a doped buffer layer into an epitaxial device/active layer of claim 7,
wherein basal plane dislocations (BPDs) did not expand until a power density of 13 kW/cm² was applied; and
wherein ˜50 cm⁻² expanded.

9. A device capable of preventing basal plane dislocations (BPDs) from expanding from a SiC substrate or a doped buffer layer into an epitaxial device/active layer of claim 8
wherein drift layer carrier lifetime is not reduced; and
wherein BPD expansion is prevented at current densities up to 12 kA/cm².
